(19) United States
(12) Patent Application Publication
(10) Pub. No.: US 2009/0039482 A1
(43) Pub. Date: Feb. 12, 2009

(54) Package Including a Microprocessor & Fourth Level Cache

(76) Inventors: Jiangqi He, Gilbert, AZ (US); Bao Shu Xu, Shanghai (CN); Xiang Yin Zeng, Shanghai (CN)

Correspondence Address: BLAKELY SOKOLOFF TAYLOR & ZAFMAN LLP, 1279 OAKMEAD PARKWAY, SUNNYVALE, CA, 94085-4040, US

(21) Appl. No.: 10/581,755

(22) PCT Filed: Aug. 31, 2005
(86) PCT No.: PCT/CN05/01373

§ 371 Date: Jun. 5, 2006

(51) Int. Cl. H01L 23/495; H01L 23/50; H01L 21/60

(52) U.S. Cl. 257/675; 257/691; 438/109; 257/E23.031; 257/E23.079; 257/E21.506

(57) ABSTRACT

A method, apparatus and system with a package including an integrated circuit disposed between die including a microprocessor and a die including a fourth level cache.

### TECHNICAL FIELD

The invention relates to the field of microelectronics and more particularly, but not exclusively, to packaging a microprocessor and a fourth level cache.

### BACKGROUND

The evolution of integrated circuit designs has resulted in higher operating frequency, increased numbers of transistors, and physically smaller devices. This continuing trend has further resulted in ever increasing bus speeds and demands on signal integrity. These demands in turn have generated ever increasing demands on interconnect ingredients, including increased trace routing densities that result from increased numbers of signals, and reduced inductance and reduced capacitance connector ingredients with increasing pin count. The described evolution of competing technology requirements is expected to continue into the foreseeable future.

Present computer systems have a variety of subsystems and subsystem partitions. Typically, a system may use a memory controller that allocates a portion of main system memory (“memory subsystem”) capacity to each of several subsystems. A typical system 100 may share the memory subsystem among one or several microprocessors and one or several graphics processors. For example, FIG. 1 illustrates a typical single processor motherboard 108 populated with a microprocessor 102 and several memory modules 104 individually replaceable, allowing flexibility in system memory capacity.

A signal between the memory 104 and the processor 102 may travel through a connector 106, the motherboard 108, a connector for the processor (not shown) and terminate within the processor 102. The signal may degrade from the time it leaves the memory device on the module 104 as a result of, for example, bus inefficiencies, connector discontinuities, trace length, and interference from adjacent traces.

Signal degradation may be partially avoided if a microprocessor incorporates a small amount of memory, generally referred to as a cache. Cache generally may be classified as having different “levels”. For example, within or near the microprocessor circuitry, a so called “first level” cache may address the needs for highest speed memory. A first level cache may typically be characterized as very low capacity but very high speed memory. An exemplary first level cache may be on the order of 32 kilobytes (32 KB). One kilobyte is 2¹⁰ bytes, or 1024 bytes.

A “second level” cache may also be incorporated on a die that also includes a microprocessor. Generally, the circuitry comprising a second level cache is separate from the circuitry comprising a microprocessor, but being disposed on the same die, may communicate with the microprocessor at much higher speeds than a system memory but lower speeds than a first level cache. While the capacity of a second level cache may typically be constrained by overall die area considerations and the desire to increase microprocessor die per wafer, a second level cache may typically have a memory capacity orders of magnitude larger than a first level cache and orders of magnitude smaller than a system memory capacity. An exemplary second level cache may be on the order of 256 KB, orders of magnitude larger than a typical first level cache.

Similarly, a “third level” cache may have still larger capacity than a second level cache but orders of magnitude smaller capacity than a system memory. Further, a third level cache may have lower signaling speed than a second level cache and orders of magnitude faster signaling speed than a system memory whose signal may degrade as it passes through various trace lengths, connectors, etc. An exemplary third level cache may be on the order of several megabytes. A megabyte is 2²⁰ bytes, or 1,024 kilobytes, approximately three orders of magnitude larger than a kilobyte.

Depending on bus speed, system memory capacity, process technology, signaling voltage, and other signaling attributes, a microprocessor may demand more memory storage at higher speeds than, either, or both, a system memory and a microprocessor die can accommodate. An exemplary system level memory capacity may range from a few gigabytes for a mobile application to hundreds of gigabytes for server applications. A gigabyte is 2³⁰ bytes, or 1024 megabytes. A gigabyte is approximately three orders of magnitude greater than a megabyte and approximately six orders of magnitude greater than a kilobyte.

Commonly used, presently available packaging techniques generally use all available space and preclude use of additional components. For example, FIG. 2 illustrates a typical package 200, including a microprocessor 206. The package 200 may have capacitors 202 disposed on a substrate 208 of the package, the capacitors 202 aiding in power delivery to the microprocessor under high frequency fluctuations of current. The capacitors 202 may be disposed in a cavity formed by a connector 210. The substrate 208 may have a Land Grid Array electrical interconnect coupled to a motherboard 214 by way of a connector pin 212. Further, a die 206 may be thermally coupled to an integrated heat spreader 204. Thus, despite the potential need for increased capacity of high speed memory, space for additional components may often be unavailable on a typical package including a microprocessor.

### BRIEF DESCRIPTION OF THE DRAWINGS

FIG. 1 illustrates a prior art motherboard assembly including a microprocessor subsystem, a memory subsystem and a memory controller as distinct components.

FIG. 2 illustrates a side view cross-section of a prior art package including multiple die and land side capacitors, the package electrically coupled to a land grid array connector.

FIG. 3 illustrates a side view cross section of an embodiment of a package including multiple die, a thin film capacitor, and a land side, flip chip ball grid array mounted memory device, the package electrically coupled to a land grid array connector.

FIG. 4 illustrates a side view cross section of an embodiment of a package including multiple die, a thin film capacitor, and a land side, wire lead frame mounted memory device, the package electrically coupled to a land grid array connector.

FIG. 5 illustrates a plan view of an embodiment of a package including multiple die, one of the die a memory device, mounted to a top side of the package substrate.

FIG. 6 illustrates a plan view of an embodiment of a package including multiple die mounted to a top side of the package substrate and a memory device mounted to a land side of the package substrate.

FIG. 7 illustrates a system schematic incorporating an embodiment of a package including multiple die, one of the die including a memory device.

FIG. 8 illustrates a method of including an integrated circuit disposed on tow or more electrically coupled die in a package, and further including the package in a system.

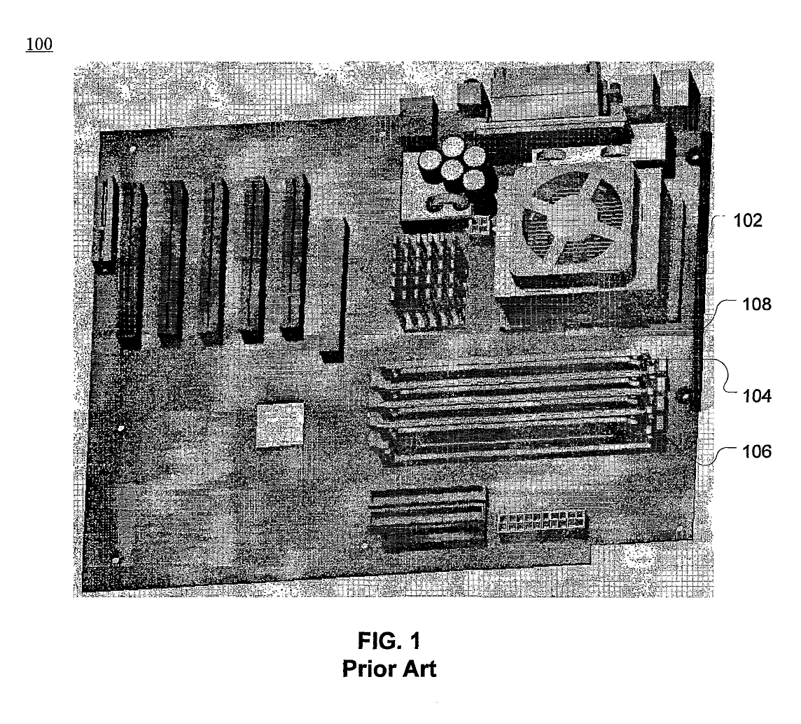

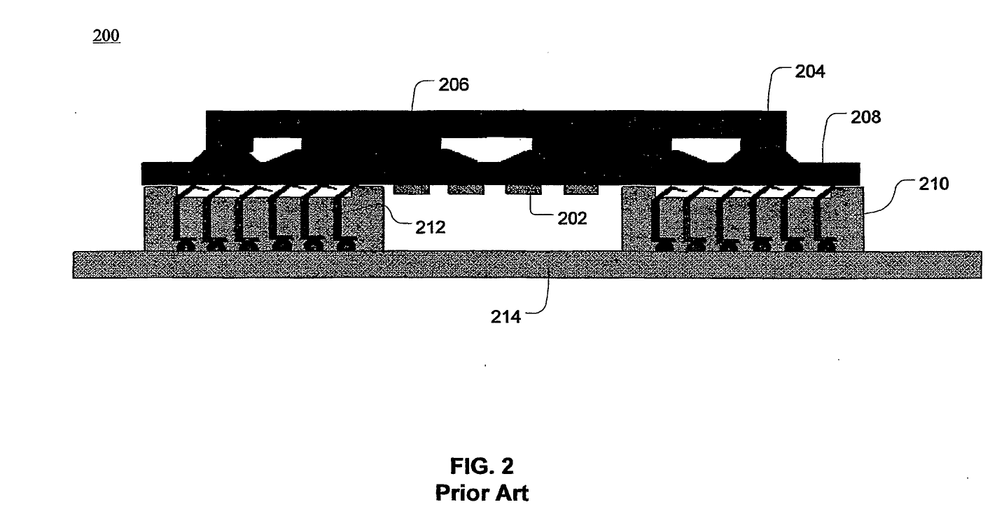

### DETAILED DESCRIPTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the intended scope of the embodiments presented. It should also be noted that directions and references (e.g., up, down, top, bottom, primary side, backside, etc.) may be used to facilitate the discussion of the drawings and are not intended to restrict the application of the embodiments of this invention. Therefore, the following detailed description is not to be taken in a limiting sense and the scope of the embodiments of the present invention is defined by the appended claims and their equivalents.

To provide increased system performance, a microprocessor may need increased capacity of high speed memory over that easily deliverable by a third level cache (perhaps on the order of several megabytes) or a system memory (perhaps ranging from several gigabytes to hundreds of gigabytes). While space for additional components may often be difficult to incorporate on a package including a microprocessor, addition of one or more memory components coupled to a microprocessor package may be desirable. A memory, architecturally disposed between a third level cache and a system memory, may be termed a fourth level cache. A typical fourth level cache may be characterized by having high speed relative to a system memory bus and large capacity relative to a third level cache integrated on a die comprising a microprocessor. A typical fourth level cache according to one embodiment may have a capacity on the order of hundreds of megabytes (MB). Another exemplary embodiment may have a fourth level cache ranging between 512 MB and 1 gigabyte (GB).

According to the present state of the art, a fourth level cache, if used, may need to be integrated either on a die comprising a microprocessor or on a motherboard to which a package including the die may be coupled. Increasing die area to facilitate a fourth level cache may not be economical and coupling a fourth level cache to a microprocessor through a connector may degrade signaling speed or quality or both.

FIG. 3 illustrates a cross-section view of an embodiment of a package 300 including an integrated circuit disposed on two or more electrically coupled die 308. In one embodiment, a first die 308 may include a microprocessor and a second die 302 may include a memory device. An exemplary embodiment of a memory device 302 may comprise a fourth level cache. Another embodiment of the package 300 may further include a memory controller, not shown. Still another embodiment may include a thin film capacitor 312 electrically coupled to a die 308 and/or 302. In one embodiment, the thin film capacitor 312 may be integral to a package substrate 310.

As shown in FIG. 3, a die 302 may be disposed on a land side of the package substrate 310. In one embodiment, the die 302 disposed on a land side of the package may be a memory device. In another embodiment, the die 302 disposed on a land side of the package may be coupled to the package substrate 310 using one or more solder balls 304. An exemplary embodiment of the die 302 may include a fourth level cache.

Further, an embodiment of a package, as shown in FIG. 3, may include a substrate 310 including a land grid array (LGA), not shown, electrically coupled to one of the die 308 and/or 302. In another embodiment, the substrate may include a Pin Grid Array (PGA) electrical interconnect. Still further, an embodiment may include a third, a fourth, a fifth, and even more, die 308. In one embodiment, the multiple die 308 may individually and independently include a microprocessor, a memory device, a memory controller, an application specific integrated circuit (ASIC), a graphics processor, a signal processor, a radio transceiver, or another integrated circuit.

As further shown in FIG. 3, an embodiment may include an integrated heat spreader 306 thermally coupled to a die 308. Still further, an embodiment may include a substrate 310 coupled to a land grid array connector 314, the land grid array connector including electrical connection elements 316 capable of coupling the land grid array on the substrate 310 to a printed circuit board 318. In another embodiment, the substrate 310 may be coupled to a Pin Grid Array connector (not shown), the PGA connector including electrical connection elements capable of coupling the PGA on the substrate 310 to a printed circuit board 318. In an embodiment, the printed circuit board 318 may be a motherboard. In another embodiment, the printed circuit board 318 may be a board forming a subassembly capable of further coupling to a motherboard. In a server, a motherboard may also be referred to as a baseboard.

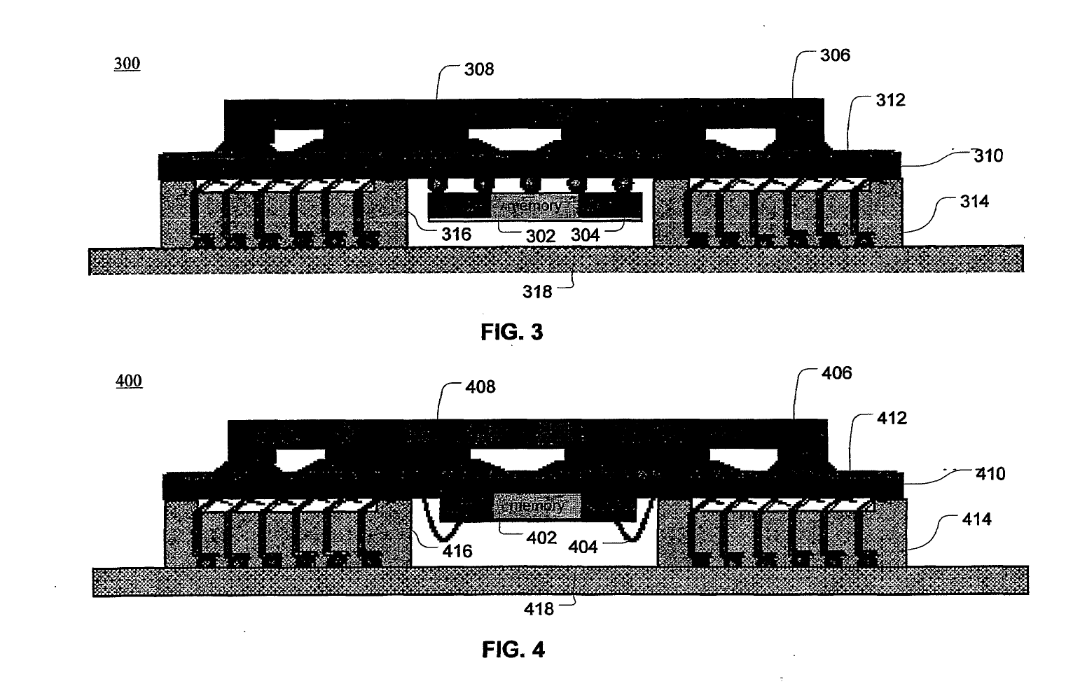

An embodiment illustrated by FIG. 4 may be similar to the embodiments discussed in relation to FIG. 3. FIG. 4 illustrates a cross-section view of an embodiment of a package 400 including an integrated circuit disposed on two or more electrically coupled die 408. In one embodiment, a first die 408 may include a microprocessor and a second die 402 may include a memory device. The second die 402 may be disposed on a land side of the package substrate 410. In one embodiment, the die 402 disposed on a land side of the package is a memory device. Further, an exemplary embodiment of the memory device 402 may comprise a fourth level cache. In another embodiment, the die 402 disposed on a land side of the package may be coupled to the package substrate 410 using one or more wire lead frames 404. An embodiment as illustrated in FIG. 4 may further include a thin film capacitor 412, an integrated heat spreader 406, a land grid array (not shown) integral to a package substrate 410, a land grid array connector 414, and an electrical connection element 416 disposed between a land pad in the land grid array (not shown) and a printed circuit board 418.

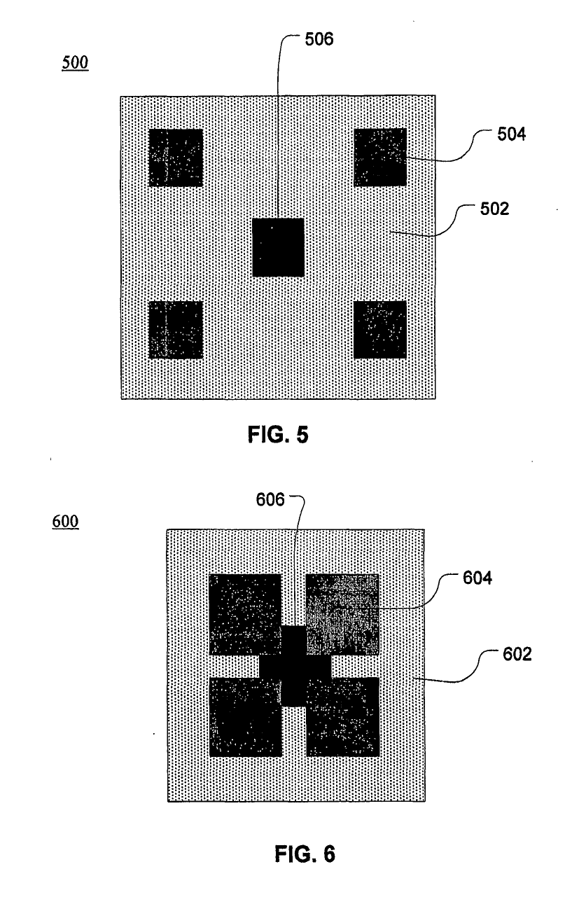

FIG. 5 illustrates plan view of an embodiment of a package 500 with a memory device 506 disposed on a same side of the package substrate 502 as another die 504. In an embodiment, the die 504 may include a microprocessor, a memory device, a memory controller, an application specific integrated circuit (ASIC), a graphics processor, a signal processor, a radio transceiver, or any other integrated circuit. In another embodiment, the memory device 506 may include a fourth level cache.

FIG. 6 illustrates plan view of an embodiment of a package 600 with a memory device 606 disposed on a land side of the package substrate 602 and another die 604 disposed on a top side of the package substrate 602. In an embodiment, the die 604 may include a microprocessor, a memory device, a memory controller, an application specific integrated circuit (ASIC), a graphics processor, a signal processor, a radio transceiver, or any other integrated circuit.

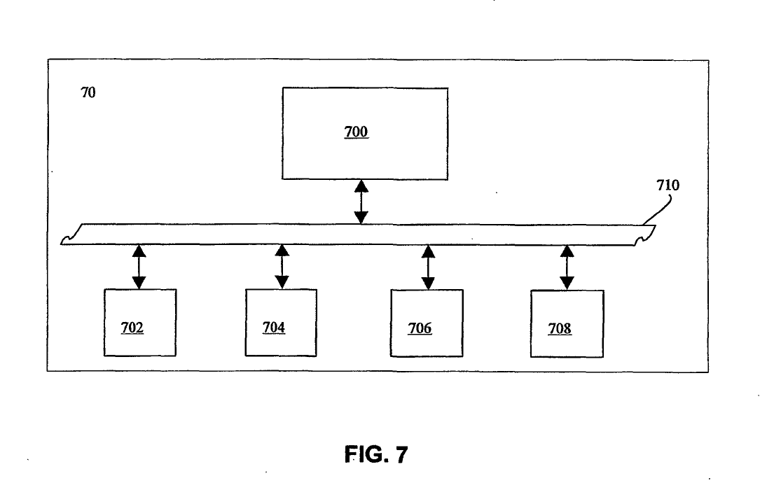

FIG. 7 illustrates a schematic representation of one of many possible system embodiments. In an embodiment, the package containing an integrated circuit 700 may include a first die including a microprocessor and a second die including a memory device as illustrated in FIG. 3-FIG. 6. In an alternate embodiment, the integrated circuit package may include an application specific integrated circuit (ASIC). Integrated circuits found in chipsets (e.g., graphics, sound, and control chipsets) or memory may also be packaged in accordance with embodiments of this invention.

For an embodiment similar to the embodiment depicted in FIG. 7, the system 70 may also include a main memory 702, a graphics processor 704, a mass storage device 706, and an input/output module 708 coupled to each other by way of a bus 710, as shown. Examples of the memory 702 include but are not limited to static random access memory (SRAM) and dynamic random access memory (DRAM). Examples of the mass storage device 706 include but are not limited to a hard disk drive, a flash drive, a compact disk drive (CD), a digital versatile disk drive (DVD), and so forth. Examples of the input/output modules 708 include but are not limited to a keyboard, cursor control devices, a display, a network interface, and so forth. Examples of the bus 710 include but are not limited to a peripheral control interface (PCI) bus, PCI Express bus, Industry Standard Architecture (ISA) bus, and so forth. In various embodiments, the system 70 may be a wireless mobile phone, a personal digital assistant, a pocket PC, a tablet PC, a notebook PC, a desktop computer, a set-top box, an audio/video controller, a DVD player, a network router, a network switching device, or a server.

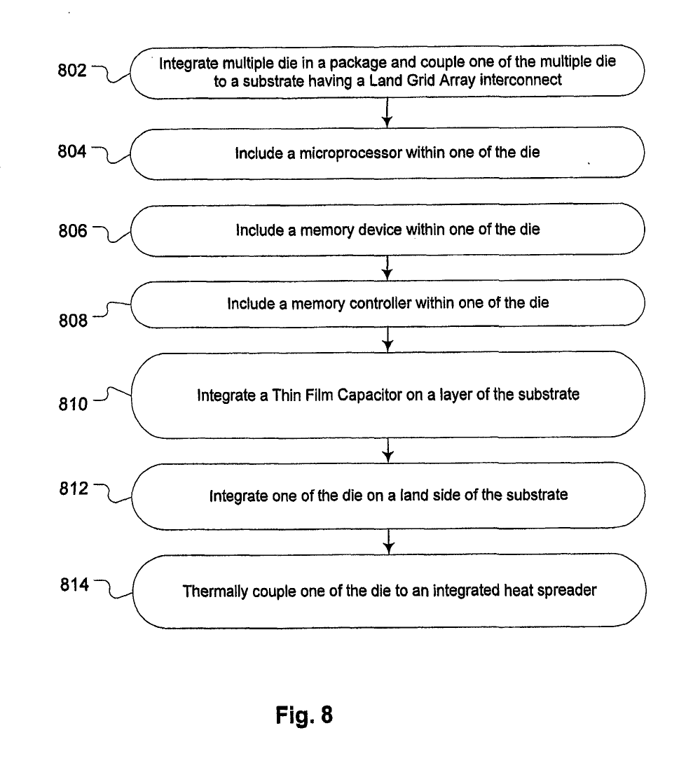

FIG. 8 illustrates one embodiment of a method of packaging a memory device in a package further including a microprocessor. One embodiment of a method may integrate multiple die in a package and couple one of the multiple die to a substrate having a Land Grid Array (LGA) interconnect 802. Another embodiment may include a die comprising a microprocessor 804. Still another embodiment may include a die comprising a memory device 806. A further embodiment may include a die comprising a memory controller 808. Yet another embodiment may integrate a thin film capacitor on a layer of a package substrate 810. One embodiment may integrate a die on a land side of the substrate 812. Further, an embodiment may couple a die to an integrate heat spreader 814.

Although specific embodiments have been illustrated and described herein for purposes of description of an embodiment, it will be appreciated by those of ordinary skill in the art that a wide variety of alternate and/or equivalent implementations calculated to achieve similar purposes may be substituted for the specific embodiments shown and described without departing from the scope of the present disclosure. For example, an alternative embodiment may exist where an integrated heat spreader integrates a cooling solution, such as a cold plate. Another embodiment may couple multiple die on a land side of a package substrate. Still another embodiment may use discrete capacitor components in lieu of, or in addition to, a thin film capacitor integral to the substrate. Yet another embodiment may exist wherein the package is further coupled to other components, e.g., retention mechanism components, power delivery components, or thermal solution components, forming a subassembly to interface with features on a motherboard. Still another embodiment may use a substrate with a pin grid array in conjunction with a land grid array.

Those with skill in the art will readily appreciate that the present invention may be implemented using a very wide variety of embodiments. This detailed description is intended to cover any adaptations or variations of the embodiments discussed herein. Therefore, it is manifestly intended that this invention be limited only by the claims and the equivalents thereof.

What is claimed is:

1. An apparatus comprising:
a package including an integrated circuit disposed on two or more electrically coupled die, the first die including a microprocessor and the second die including a memory device;
a substrate of the package including one selected from the group consisting of a Land Grid Array, a Pin Grid Array, and a combination thereof electrically coupled to one of the die.

2. The apparatus of claim 1, further comprising a memory controller electrically coupled to the memory device.

3. The apparatus of claim 1, further comprising a thin film capacitor integral to the substrate.

4. The apparatus of claim 1, the second die disposed on a land side of the substrate.

5. The apparatus of claim 1, further comprising a third die including a second microprocessor, a fourth die including a third microprocessor, and a fifth die including a fourth microprocessor.

6. The apparatus of claim 5, the second die electrically coupled by one selected from the group including a wirebond electrical interconnect, a flip-chip ball grid array electrical interconnect, a lead frame interconnect, and a combination thereof.

7. The apparatus of claim 1 further comprising a die including one selected from the group including a memory device, a memory controller, an application specific integrated circuit (ASIC), a graphics processor, a signal processor, a radio transceiver, and a combination thereof.

8. The memory device of claim 7 further comprising a fourth level cache.

9. The apparatus of claim 1, the package further including an integrated heat spreader thermally coupled to one or more of the die.

10. A method comprising:
including an integrated circuit disposed on two or more electrically coupled die in a package, the first die including a microprocessor and the second die including a memory device; and
electrically coupling a substrate of the package including one selected from the group consisting of a Land Grid Array, a Pin Grid Array, and a combination thereof to at least one of the die.

11. The method of claim 10, further comprising electrically coupling a memory controller to the memory device.

12. The method of claim 10 wherein the memory device further comprises a fourth level cache.

13. The method of claim 10, further comprising integrating a thin film capacitor with the substrate.

14. The method of claim 10, disposing the second die on a land side of the substrate.

15. The method of claim 10, further including in the package a third die including a second microprocessor, a fourth die including a third microprocessor, and a fifth die including a fourth microprocessor.

16. The method of claim 15, the second die electrically coupled by one selected from the group including a wirebond electrical interconnect, a flip-chip ball grid array electrical interconnect, a lead frame interconnect, and a combination thereof.

17. The method of claim 10, further thermally coupling an integrated heat spreader to one or more of the die.

18. A system comprising:
a package including an integrated circuit disposed on two or more electrically coupled die, the first die including a microprocessor and the second die including a memory device;
a substrate of the package including one selected from the group consisting of a Land Grid Array, a Pin Grid Array, and a combination thereof electrically coupled to at least one of the die; and
a mass storage device coupled to the package.

19. The system of claim 18 wherein the memory device further comprises a fourth level cache.

20. The system of claim 18, further comprising:
a dynamic random access memory coupled to the integrated circuit; and
an input/output interface coupled to the integrated circuit.

21. The system of claim 20, wherein the input/output interface comprises a networking interface.

22. The system of claim 18, wherein the system is a selected one of a group comprising a set-top box, a media-center personal computer, a digital versatile disk player, a server, a personal computer, a mobile personal computer, a network router, and a network switching device.

23. The system of claim 18, the memory device disposed in a recess formed by a land grid array socket, the package electrically coupled to the land grid array connector.

24. The system of claim 23, the land grid array connector coupled to a printed circuit board assembly capable of further coupling to a motherboard.
